(19) United States
(12) Patent Application Publication
(10) Pub. No.: US 2025/0338491 A1
(43) Pub. Date: Oct. 30, 2025

(54) MEMORY AND FORMING METHOD THEREOF, AND MEMORY SYSTEM

(71) Applicant: YANGTZE MEMORY TECHNOLOGIES CO., LTD., Wuhan (CN)

(72) Inventors: Zichen Liu, Wuhan (CN); Yanhong Wang, Wuhan (CN); Yaqin Liu, Wuhan (CN); Liang Chen, Wuhan (CN); Wei Liu, Wuhan (CN)

(21) Appl. No.: 18/965,643

(22) Filed: Dec. 2, 2024

(30) Foreign Application Priority Data
Apr. 29, 2024 (CN) 202410537553.4

(51) Int. Cl. H10B 12/00; G11C 5/02; G11C 5/06

(52) U.S. Cl. CPC H10B 12/50; G11C 5/025; G11C 5/06; H10B 12/09; H10B 12/312; H10B 12/482

(57) ABSTRACT

According to one aspect of the present disclosure, a memory is provided. The memory may include a plurality of blocks each including a first semiconductor structure. The first semiconductor structure includes a memory cell array. The memory cell array may include a plurality of storage capacitors. The storage capacitor may include a first plate, a second plate, and a dielectric layer located between the first plate and the second plate. The second plates of the plurality of storage capacitors in the block may be connected, and the second plates of the storage capacitors of at least two blocks of the plurality of blocks may be connected.

### CROSS-REFERENCE TO RELATED APPLICATIONS

The present application claims the benefit of priority to Chinese Application No. 202410537553.4, filed on Apr. 29, 2024, which is hereby incorporated by reference in its entirety.

### TECHNICAL FIELD

The present disclosure relates to the technical field of semiconductors, for example, to a memory and a forming method thereof, and a memory system.

### BACKGROUND

With the continuous development of the current science and technology, semiconductor devices are widely applied in various electronic apparatuses and electronic products. For example, a dynamic random access memory (DRAM) as a volatile memory is a commonly used semiconductor memory device in a computer.

### SUMMARY

According to one aspect of the present disclosure, a memory is provided. The memory may include a plurality of blocks each including a first semiconductor structure. The first semiconductor structure includes a memory cell array. The memory cell array may include a plurality of storage capacitors. The storage capacitor may include a first plate, a second plate, and a dielectric layer located between the first plate and the second plate. The second plates of the plurality of storage capacitors in the block may be connected, and the second plates of the storage capacitors of at least two blocks of the plurality of blocks may be connected.

In some implementations, each of the first semiconductor structures of at least part of the plurality of blocks further may include a first conductive connection structure. In some implementations, the first conductive connection structure may be connected to the second plate.

In some implementations, the plurality of blocks may be arranged in an array along a second direction perpendicular to a first direction and a third direction perpendicular to the first direction. In some implementations, the second direction may intersect the third direction, and the first direction may be a thickness direction of the block. In some implementations, each block further comprises a memory region and a contact region. In some implementations, the contact region may be located on two opposite sides of the memory region along the second direction and two opposite sides of the memory region along the third direction. In some implementations, the first conductive connection structure is located in the contact region of the block.

In some implementations, the first conductive connection structure may be located in the contact region at a corner of the block.

In some implementations, each block further includes a second semiconductor structure disposed as being stacked with the first semiconductor structure along the first direction. In some implementations, the second semiconductor structure may include a peripheral circuit. In some implementations, the first conductive connection structure may be located between the second semiconductor structure and the second plate. In some implementations, the memory cell array may further include a plurality of transistors. In some implementations, each transistor may be located between the storage capacitor and the second semiconductor structure. In some implementations, each transistor may include a source, a channel region, and a drain arranged along the first direction, and one of the source and the drain of the transistor may be connected to the first plate of the storage capacitor. In some implementations, the first semiconductor structure may further include a plurality of bit lines. In some implementations, the bit line may be located between the transistor and the second semiconductor structure. In some implementations, the other one of the source and the drain of the transistor may be connected to the bit line.

In some implementations, the second plate may extend from the memory region into the contact region, the second plate located in the memory region may include a first portion extending along the first direction and a second portion extending along a direction perpendicular to the first direction. In some implementations, the second plate located in the contact region extends along the direction perpendicular to the first direction. In some implementations, a distance between the second plate in the contact region and the transistor along the first direction may be less than a distance between the second portion of the second plate in the memory region and the transistor along the first direction.

In some implementations, the peripheral circuit may be located in the memory region. In some implementations, the memory cell array may be located in the memory region. In some implementations, projections of the memory region in which the memory cell array may be located and the memory region in which the peripheral circuit may be located along a first plane overlap. In some implementations, the first plane may be perpendicular to the first direction.

In some implementations, the memory may include at least one chip. In some implementations, the chip may be a plurality of banks. In some implementations, the bank may include the plurality of blocks. In some implementations, the second plates of the storage capacitors of the plurality of blocks in the bank may all be connected, and the second plates of the storage capacitors of at least two banks of the plurality of banks may be connected.

In some implementations, the second plates of the storage capacitors of the plurality of banks within the chip may all be connected.

In some implementations, the second semiconductor structure may include a first interconnect layer located between the first semiconductor structure and the peripheral circuit. In some implementations, the first interconnect layer may include a first interconnect structure. In some implementations, the first semiconductor structure may include a second interconnect layer located between the memory cell array and the second semiconductor structure. In some implementations, the second interconnect layer may include a second interconnect structure. In some implementations, the peripheral circuit may be coupled to the memory cell array through the first interconnect structure and the second interconnect structure.

In some implementations, the second semiconductor structure may further include a substrate and a bus layer. In some implementations, the peripheral circuit may be located in the substrate, and the substrate may be located between the bus layer and the first semiconductor structure.

In some implementations, the second semiconductor structure may further include a second conductive connection structure. In some implementations, the second conductive connection structure may extend through the substrate. In some implementations, one end of the second conductive connection structure may be connected to a bus in the bus layer, and the other end of the second conductive connection structure may be connected to the first interconnect structure.

In some implementations, the second semiconductor structure may further include a pad-out interconnect layer. In some implementations, the peripheral circuit may be located between the pad-out interconnect layer and the first semiconductor structure.

According to a further aspect of the present disclosure, a memory system is provided. The memory system may include a memory. The memory may include a plurality of blocks. Each block may include a first semiconductor structure. The first semiconductor structure may include a memory cell array. The memory cell array may include a plurality of storage capacitors. The storage capacitor may include a first plate, a second plate, and a dielectric layer located between the first plate and the second plate. The second plates of the plurality of storage capacitors in the block may be connected, and the second plates of the storage capacitors of at least two blocks of the plurality of blocks may be connected. The memory system may include controller configured to control the memory.

According to a further aspect of the present disclosure, a method of forming a memory is provided. The method may include forming a plurality of blocks. The forming each block may include forming a first semiconductor structure. The first semiconductor structure may include a memory cell array. The memory cell array may include a plurality of storage capacitors. The storage capacitor may include a first plate, a second plate, and a dielectric layer located between the first plate and the second plate. The second plates of the plurality of storage capacitors in the block may be connected, and the second plates of the storage capacitors of at least two blocks of the plurality of blocks may be connected.

In some implementations, the forming the first semiconductor structure may further include forming a first conductive connection structure in each of the first semiconductor structures of at least part of the blocks. In some implementations, the first conductive connection structure may be connected to the second plate.

In some implementations, the plurality of blocks may be arranged in an array along a second direction perpendicular to a first direction and a third direction perpendicular to the first direction. In some implementations, the second direction intersects the third direction, and the first direction is a thickness direction of the block, wherein each block may include a memory region and a contact region. In some implementations, the contact region may be located on two opposite sides of the memory region along the second direction and two opposite sides of the memory region along the third direction. In some implementations, the forming the first conductive connection structure may include forming the first conductive connection structure in the contact region of the block.

In some implementations, the forming the plurality of storage capacitors may include providing a stop layer and a stack structure located on the stop layer. In some implementations, the stack structure may include a sacrificial layer and a dielectric layer that are alternately stacked, and both the stop layer and the stack structure are distributed in the memory region and the contact region. In some implementations, the forming the plurality of storage capacitors may include forming a plurality of first grooves extending through the stack structure and the stop layer along the first direction in the memory region. In some implementations, the forming the plurality of storage capacitors may include forming the first plate in the first groove. In some implementations, the forming the plurality of storage capacitors may include forming a plurality of second grooves extending through the stack structure along the first direction in the memory region, and removing the stack structure in the contact region. In some implementations, the forming the plurality of storage capacitors may include removing the sacrificial layer in the memory region through the second groove, to form a filling region. In some implementations, the forming the plurality of storage capacitors may include forming the dielectric layer and the second plate on the second groove, the filling region, and the stop layer of the contact region. In some implementations, the forming the plurality of storage capacitors may include removing the second plates in the contact regions of part of the blocks.

In some implementations, the forming each block may further include forming a second semiconductor structure disposed as being stacked with the first semiconductor structure along the first direction. In some implementations, the second semiconductor structure may include a peripheral circuit, and the first conductive connection structure may be located between the second semiconductor structure and the second plate. In some implementations, the forming the first semiconductor structure may include forming a plurality of transistors. In some implementations, the transistor may be located between the storage capacitor and the second semiconductor structure. In some implementations, the transistor may include a source, a channel region, and a drain arranged along the first direction, and one of the source and the drain of the transistor may be connected to the first plate of the storage capacitor. In some implementations, the forming the first semiconductor structure may include forming a plurality of bit lines. In some implementations, the bit line may be located between the transistor and the second semiconductor structure, and the other one of the source and the drain of the transistor may be connected to the bit line.

In some implementations, the second plate may extend from the memory region into the contact region, the second plate located in the memory region may include a first portion extending along the first direction and a second portion extending along a direction perpendicular to the first direction, and the second plate located in the contact region may extend along the direction perpendicular to the first direction. In some implementations, a distance between the second plate in the contact region and the transistor along the first direction may be less than a distance between the second portion of the second plate in the memory region and the transistor along the first direction.

In some implementations, the forming the first semiconductor structure may further include forming a third conductive connection structure while forming the first conductive connection structure. In some implementations, the third conductive connection structure may be connected to the bit line.

In some implementations, the forming the second semiconductor structure may include providing a substrate that includes a first side and a second side that are opposite along a thickness direction of the substrate. In some implementations, the forming the second semiconductor structure may include forming the peripheral circuit in the substrate from the first side. In some implementations, the forming the second semiconductor structure may include forming a first interconnect layer on the peripheral circuit from the first side. In some implementations, the first interconnect layer may include a first interconnect structure.

In some implementations, the forming the second semiconductor structure may further include forming a bus layer on the substrate from the second side. In some implementations, the forming the second semiconductor structure may further include forming a pad-out interconnect layer on the bus layer from the second side.

In some implementations, the forming the first semiconductor structure may further include forming a second interconnect layer. In some implementations, the second interconnect layer may include a second interconnect structure, and the bit line may be located between the memory cell array and the second interconnect layer.

In some implementations, the method may further include bonding the first interconnect layer of the second semiconductor structure and the second interconnect layer of the first semiconductor structure.

In the examples of the present disclosure, the storage capacitor comprises the first plate, the second plate, and the dielectric layer. The second plates of the plurality of storage capacitors in the blocks are connected, and the second plates of the storage capacitors of at least two blocks of the plurality of blocks are connected. That is, the second plates of one block are connected to the second plates of another block. In a first aspect, since the second plates of the storage capacitors of at least two blocks of the plurality of blocks are connected, the number of first conductive connection structures for leading out the second plates of the storage capacitors can be reduced, such that the area of the memory can be reduced. In a second aspect, the second plates of the storage capacitors of at least two blocks are connected in the examples of the present disclosure, from the perspective of a manufacturing process, a mask required for a disconnecting process for the second plate is unnecessary in the present disclosure, and the disconnecting process for the second plate can be omitted, such that process operations can be reduced, thereby reducing manufacturing costs.

### BRIEF DESCRIPTION OF THE DRAWINGS

FIG. 1 is a schematic structural diagram of an electronic apparatus provided by an example of the present disclosure.

FIG. 2 is a schematic structural diagram of a memory provided by an example of the present disclosure.

FIG. 3 is a schematic structural cross-sectional view I of a memory provided by an example of the present disclosure.

FIG. 4 is a schematic structural cross-sectional view II of a memory provided by an example of the present disclosure.

FIG. 5 is a schematic structural cross-sectional view III of a memory provided by an example of the present disclosure.

FIG. 6A is a schematic structural diagram I of a bank provided by an example of the present disclosure.

FIG. 6B is a schematic structural diagram II of a bank provided by an example of the present disclosure.

FIG. 7 is a schematic structural composition diagram of a memory provided by an examples of the present disclosure.

FIG. 8 is a schematic structural diagram of a memory cell array and a peripheral circuit of a memory provided by an example of the present disclosure.

FIG. 9 is a flow chart I of a forming method of a memory provided by an example of the present disclosure.

FIG. 10 is a flow chart II of a forming method of a memory provided by an example of the present disclosure.

FIGS. 11 to 21 are schematic structural diagrams of a forming process of a memory provided by an example of the present disclosure.

### DETAILED DESCRIPTION

Exemplary implementations disclosed by the present disclosure will be described below in more details with reference to the drawings. Although the exemplary implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey a scope disclosed by the present disclosure to those skilled in the art.

In the following description, numerous specific details are given in order to provide a more thorough understanding of the present disclosure. However, it is apparent to those skilled in the art that the present disclosure may be practiced without one or more of these details. In other examples, some technical features well-known in the field are not described in order to avoid confusion with the present disclosure. That is, not all the features of the actual examples are described herein, and well-known functions and structures are not described in detail.

In the drawings, like reference numerals denote like elements throughout the specification.

It is to be understood that, spatially relative terms, such as “beneath”, “below”, “lower”, “under”, “over”, “upper”, and the like, may be used herein for ease of description to describe the relationship between one element or feature and other elements or features as illustrated in the figures. It is to be understood that the spatially relative terms are intended to further encompass different orientations of a device in use or operation in addition to the orientation depicted in the figures. For example, if the device in the drawings is turned over, then the elements or the features described as “below” or “under” or “beneath” other elements or features may be oriented “on” the other elements or features. Thus, the exemplary terms, “below” and “beneath”, may comprise both upper and lower orientations. The device may be orientated otherwise (rotated by 90 degrees or in other orientations), and the spatially descriptive terms used herein are interpreted accordingly.

The terms used here are only intended to describe the examples, and are not used as limitations to the present disclosure. As used here, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more other features, integers, steps, operations, elements, components, and/or groups. As used here, a term “and/or” comprises any and all combinations of related items listed.

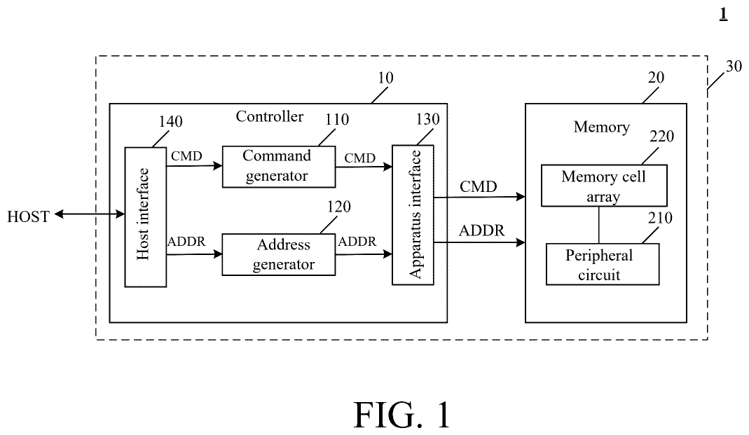

FIG. 1 is a schematic diagram of an electronic apparatus 1 shown according to an example of the present disclosure. The electronic apparatus 1 can be a mobile phone, a desktop computer, a laptop computer, a tablet, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having the memories therein.

As shown in FIG. 1, the electronic apparatus 1 may include a host HOST and a memory system 30, and the memory system 30 is provided with one or more memories 20 and a controller 10. The host HOST may include a processor of an electronic apparatus, such as a Central Processing Unit (CPU), or a System on Chip (SoC), such as an Application Processor (AP). The host HOST may be configured to send or receive data to or from the memory 20. The controller 10 is coupled to the memory 20 and the host HOST, and is configured to control the memory 20. The controller 10 may manage data stored in the memory 20, and communicate with the host HOST.

The controller 10 may be configured to control operations of the memory 20, such as read, erase, write, and refresh operations. In some implementations, the controller 10 is further configured to process Error Correction Codes (ECC) with respect to the data read from or written to the memory 20. The controller 10 may further perform any other suitable functions, for example, formatting the memory 20.

In some examples, the controller 10 and one or more memories 20 may all be integrated into various types of storage apparatuses. For example, the controller 10 may be integrated at a north bridge of a computer mainboard or directly integrated into a CPU of a computer, and the plurality of memories 20 may be integrated into a bank. In other words, the memory system 30 may be implemented and packaged into different types of end electronic products.

The controller 10 may send or receive data to or from the host HOST, and may send a command CMD and an address ADDR to the memory 20. The controller 10 may include a command generator 110, an address generator 120, an apparatus interface 130, and a host interface 140. The host interface 140 may receive the command CMD and the address ADDR from the host HOST; and the command generator 110 may generate an access command, a refresh command, and the like by decoding the command CMD received from the host HOST, and may provide the access command and the refresh command to the memory 20 through the apparatus interface 130. The access command may be a signal that instructs the memory 20 to write or read data by accessing rows of a memory cell array 220 corresponding to the address ADDR. The refresh command may be a signal that instructs the memory 20 to read and re-write the data by accessing and refreshing the rows of the memory cell array 220 corresponding to the address ADDR.

The address generator 120 in the controller 10 may generate a row address and a column address to be accessed in the memory cell array 220 by decoding the address ADDR received from the host interface 140. Furthermore, the memory 20 may generate an address of a bank to be accessed when the memory cell array 220 includes a plurality of banks.

The controller 10 may provide various signals to the memory 20 via the apparatus interface 130 to control memory operations such as write and read. For example, the controller 10 may provide a write command to the memory 20. The write command is used for instructing the memory 20 to perform a write operation to store data in the memory 20.

In some examples, the memory 20 includes at least one chip, each chip includes at least one bank, each bank includes at least one block, each block includes the memory cell array 220 and a peripheral circuit 210; and the memory cell array includes a plurality of memory cell rows and a plurality of memory cell columns, each memory cell row is coupled with one corresponding word line, and each memory cell column is coupled to one corresponding bit line. The peripheral circuit 210 may write or read data to or from the memory cell array 220 based on the command CMD and the address ADDR received from the controller 10, or may provide a control signal CTRL for refreshing memory cells included in the memory cell array 220 to a row decoder and a column decoder. In other words, the peripheral circuit 210 may perform all operations to process the data stored in the memory cell array 220. The peripheral circuit 210 may include: a control circuit of each block, such as a Sensing Amplifier (SA) circuit, a Word-Line Driver (WLD) circuit, etc.; a control circuit of each bank, such as the row decoder, the column decoder, etc.; and a control circuit of all banks, such as a command buffer, a command decoder, an address buffer, a data input/output buffer, a mode register, etc.

The memory 20 may be a Random Access Memory (RAM) such as a Dynamic Random Access Memory (DRAM), a Synchronous DRAM (SDRAM), a Static RAM (SRAM), a Double Data Rate SDRAM (DDR SDRAM), a DDR2 SDRAM, a DDR3 SDRAM, a Phase-change RAM (PRAM), a Magnetic RAM (MRAM), a Resistive RAM (RRAM), etc. The following is described by only using an example that the memory is the DRAM.

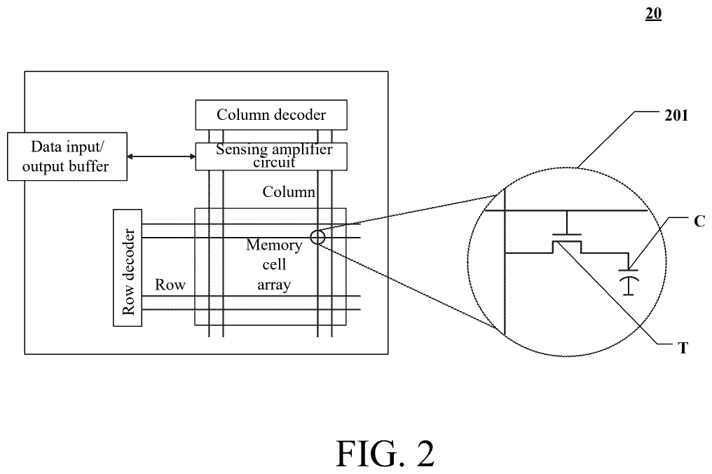

FIG. 2 is a schematic diagram of a dynamic random access memory shown according to an example of the present disclosure. Referring to FIG. 2, the dynamic random access memory includes the memory cell array and the peripheral circuit. The memory cell array includes a plurality of memory cells 201 arranged in an array, each memory cell 201 includes one transistor T and one capacitor C, a word line is coupled to a gate of the transistor T, and a bit line is coupled to a drain of the transistor T. A main action principle of the memory cell is to utilize the number of charges stored in the capacitor to represent whether one binary bit is 1 or 0. The memory cells are arranged in an array, and the memory cell array employs rows and columns to designate addresses. By designating intersections of the rows and the columns (by designating row addresses and column addresses of the DRAM), the controller may independently access each memory cell in a DRAM chip, and perform read, write, or refresh operations on data stored in the memory cell.

With the development of a dynamic random access memory technology, a size of the memory cell becomes smaller and smaller, an array architecture thereof is from 8F² to 6F², and then to 4F², and an architecture of the transistor in the memory cell is also gradually developed from a planar array transistor to a vertical gate transistor, thereby forming an architecture of a three-dimensional memory.

In some examples, as density requirements of memories keep increasing, on the basis of the architecture of a three-dimensional memory, after a memory cell array including a vertical transistor is formed on a front surface of a first wafer and a peripheral circuit is formed on a front surface of a second wafer, the front surface of the first wafer and the front surface of the second wafer are bonded, a pad structure is formed on a rear surface of the first wafer, and a power line and other signal lines are formed on the front surface of the second wafer and are located between the peripheral circuit and the memory cell array. In the above example, since the pad structure is located on the rear surface of the first wafer, a bit line needs to pass through all metal interconnect layers on the first wafer and the second wafer to reach a sensing amplifier circuit in the peripheral circuit. In one aspect, a routing length from the bit line to the sensing amplifier circuit is increased. In another aspect, crosstalk of the power line and the other signal lines on a connecting line from the bit line to the sensing amplifier circuit is increased, resulting in a reduced sense margin.

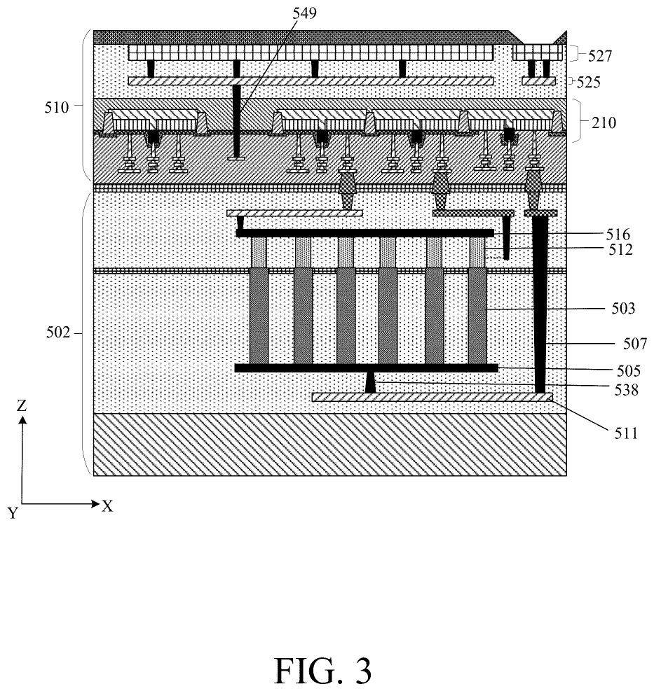

In another example, as shown in FIG. 3, after a first semiconductor structure 502 including a vertical transistor 512, a bit line 516, and a storage capacitor 503 is formed on a front surface of a first wafer and a second semiconductor structure 510 including a peripheral circuit 210 is formed on a front surface of a second wafer; the front surface of the first wafer and the front surface of the second wafer are bonded; then, the second wafer is thinned from a rear surface of the second wafer; a bus layer 525 including a power line and other signal lines is formed on the rear surface of the second wafer after a through silicon via (TSV) structure 549 is formed; and a pad-out interconnect layer 527 including a pad structure is formed on the rear surface of the second wafer. In the method provided in the above example, the pad structure is located on the rear surface of the second wafer, and the bit line 516 is connected to a sensing amplifier circuit in the peripheral circuit 210 without passing through the power line and the other signal lines. In one aspect, a routing length from the bit line 516 to the sensing amplifier circuit can be reduced. In another aspect, crosstalk of the power line and the other signal lines on a connecting line from the bit line 516 to the sensing amplifier circuit can be reduced, thereby reducing the impact on a sense margin. However, in the architecture shown in FIG. 3, a second plate 505 (an upper plate of the storage capacitor) of the storage capacitor 503 of the first semiconductor structure 502 needs to be led out through an additional first metal layer 511 and an additional contact structure 538. Compared with the solution in which the pad structure is located on the rear surface of the first wafer, in the structure shown in FIG. 3, a first conductive connection structure 507 used for leading out the second plate 505 of the storage capacitor 503 occupies a larger area, which is unfavorable for the miniaturization development of memories. In addition, the first conductive connection structure 507 needs to extend through a dielectric layer in which the storage capacitor is located along a Z-axis direction, and a size of the first conductive connection structure 507 along the Z-axis direction is large, resulting in increased process difficulty.

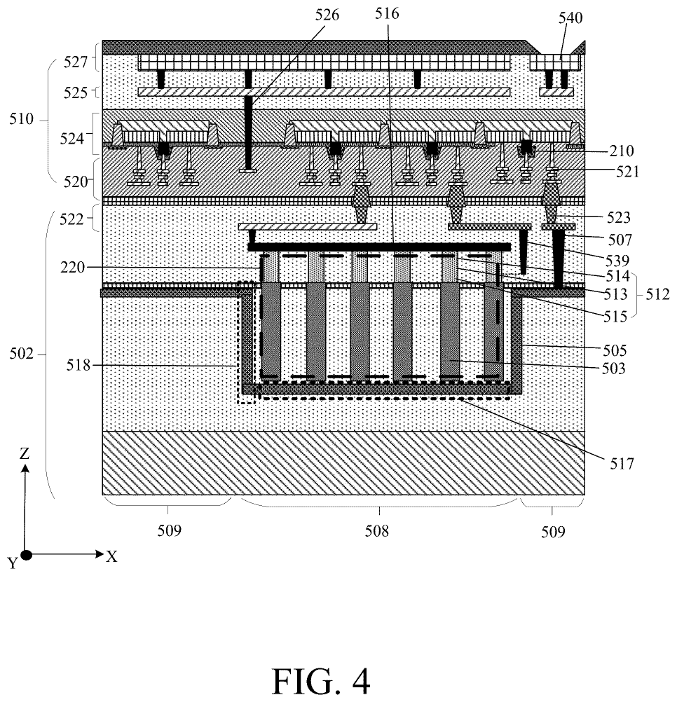

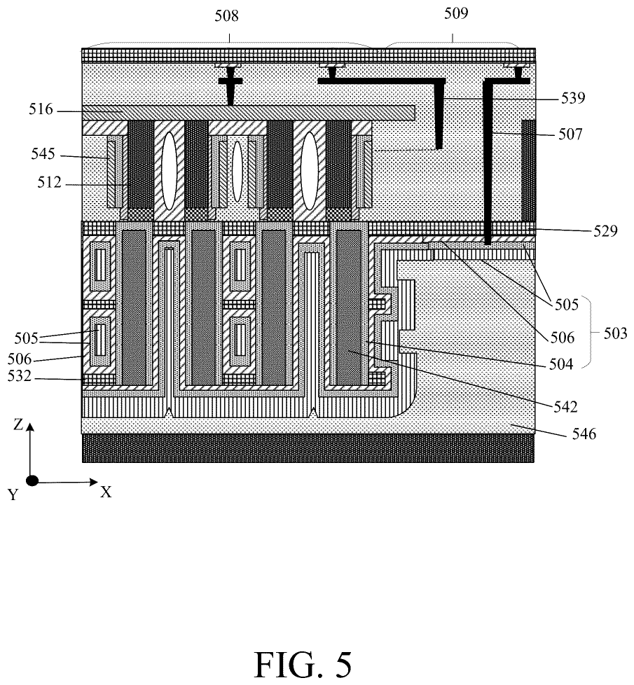

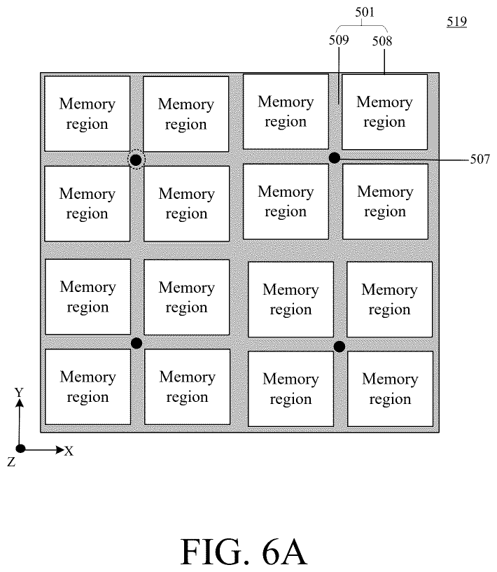

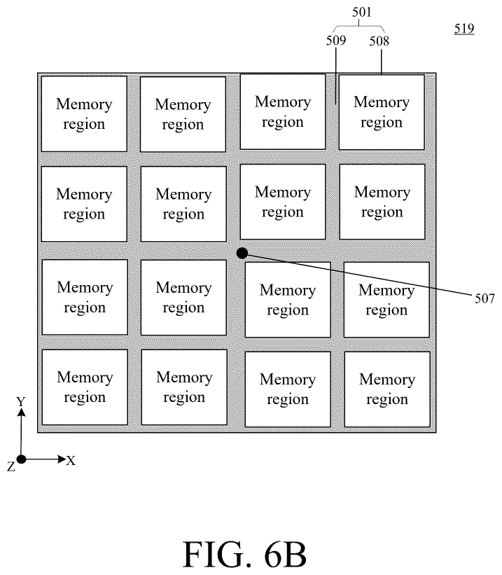

Based on one or more of the above-mentioned problems, an example of the present disclosure provides a memory (shown in FIG. 4, FIG. 5, FIG. 6A, and FIG. 6B) includes: a plurality of blocks 501, where each of the blocks 501 includes a first semiconductor structure 502, the first semiconductor structure 502 includes a memory cell array 220, the memory cell array 220 includes a plurality of storage capacitors 503, the storage capacitor 503 includes a first plate 504, a second plate 505, and a dielectric layer 506 located between the first plate 504 and the second plate 505; and the second plates 505 of the plurality of storage capacitors 503 in the block 501 are connected, and the second plates 505 of the storage capacitors 503 of at least two blocks 501 of the plurality of blocks 501 are connected.

FIG. 4 shows an example of a cross-sectional structure of a partial structure of one block. FIG. 5 shows an example of a cross-sectional structure of a partial structure of a first semiconductor structure of one block. FIG. 6A and FIG. 6B exemplarily show a composition structure of one bank.

In some examples, the first plate 504 may be used as a lower electrode of the storage capacitor 503, and the second plate 505 may be used as an upper electrode of the storage capacitor 503. A material of the dielectric layer 506 includes a high dielectric constant (high-K) material. In an example, the material of the dielectric layer 506 may include, but is not limited to, aluminum oxide (Al₂O₃), zirconium oxide (ZrO), hafnium oxide (HfO₂), etc. A material of the first plate 504 may include a conductive material, for example, may be titanium nitride. A material of the second plate 505 may include a conductive material, for example, may be titanium nitride or silicon germanium.

In an example of the present disclosure, the storage capacitor 503 includes the first plate 504, the second plate 505, and the dielectric layer 506. The second plates 505 of the plurality of storage capacitors 503 in the block 501 are connected, and the second plates 505 of the storage capacitors 503 of at least two blocks 501 of the plurality of blocks 501 are connected. That is, the second plates 505 of one block 501 are connected to the second plates 505 of another block 501. In a first aspect, since the second plates 505 of the storage capacitors 503 of at least two blocks 501 of the plurality of blocks 501 are connected, the number of first conductive connection structures for leading out the second plates 505 of the storage capacitors 503 can be reduced, such that the area of the memory 20 can be reduced. In a second aspect, the second plates 505 of the storage capacitors 503 of at least two blocks 501 are connected in the examples of the present disclosure, from the perspective of a manufacturing process, a mask required for a disconnecting process for the second plate 505 is unnecessary in the present disclosure, and the disconnecting process for the second plate 505 can be omitted, such that process operations can be reduced, thereby reducing manufacturing costs.

In some examples, as shown in FIG. 3, each of the first semiconductor structures 502 of at least part of the blocks 501 of the plurality of blocks 501 further includes a first conductive connection structure 507, and the first conductive connection structure 507 is connected to the second plate 505.

The first conductive connection structure 507 here may be a lead-out structure for leading out the second plate 505, and a material of the first conductive connection structure 507 includes a conductive material. Here, the conductive material may include at least one of a doped semiconductor material (e.g., doped silicon, doped germanium, etc.), a conductive metal nitride (e.g., titanium nitride, tantalum nitride, etc.), a metal material (e.g., tungsten, titanium, tantalum, etc.), and a metal semiconductor compound (e.g., tungsten silicide, cobalt silicide, titanium silicide, etc.).

It may be understood that, the second plates 505 of the storage capacitors 503 of at least two blocks 501 of the plurality of blocks 501 are connected in the examples of the present disclosure. Therefore, the number of the first conductive connection structures 507 may be suitably reduced as required, it is unnecessary that the dedicated first conductive connection structure 507 is disposed in every block 501. The second plates 505 of the storage capacitors 503 of part of the blocks 501 are connected. The part of the blocks 501 can share the first conductive connection structure 507, such that the number of the first conductive connection structures can be reduced, thereby reducing the area of the memory.

In an examples of the present disclosure, the second plates 505 of the storage capacitor 503 may all be connected to a same potential, for example, all be grounded or all be connected to a fixed voltage (e.g., VCC/2).

Here, the second plates 505 of the storage capacitors 503 of at least two blocks 501 of the plurality of blocks 501 are connected. It may be understood that in the plurality of blocks 501 of the chip 548 of the memory 20, the second plates 505 of the storage capacitors 503 of only at least two blocks 501 may be connected; or the second plates 505 of the storage capacitors 503 of more than two blocks 501 of the plurality of blocks 501 may be connected; or even the second plates 505 of the storage capacitors 503 of all the blocks 501 in the chip 548 of the memory 20 may be connected.

In some examples, the memory includes at least one chip 548; the chip 548 includes a plurality of banks 519, where the bank 519 includes the plurality of blocks 501; the second plates 505 of the storage capacitors 503 of the plurality of blocks 501 in the bank 519 are all connected; and the second plates 505 of the storage capacitors 503 of at least two banks 519 of the plurality of banks 519 are connected.

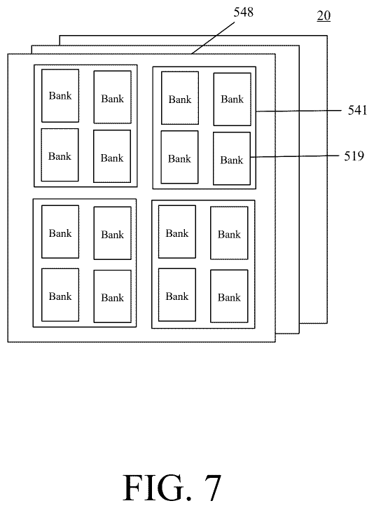

As shown in FIG. 6A and FIG. 7, the memory 20 includes the chip 548. The chip 548 includes at least one bank group 541. Each bank group 541 includes at least one bank 519, and each bank 519 includes at least one block 501. It is to be noted that the number of the chips 548 of the memory 20 and the number of the banks 519 in the bank group 541 in FIG. 7 are only an example, the present disclosure is not limited thereto. In FIG. 6A and FIG. 6B, the number of the blocks 501 in the bank 519 is only an example, the present disclosure is not limited thereto.

Here, that the second plates 505 of the storage capacitors 503 of the plurality of blocks 501 in the bank 519 are all connected may be understood as that the second plates of the storage capacitors of all the blocks 501 within the bank 519 are connected. In this way, as shown in FIG. 6B, the second plates of the storage capacitors may be led out with the bank 519 as a unit, and the number of the first conductive connection structures 507 may be reduced to be equal to the number of the banks 519, which is favorable for reducing the area of the memory. In an example of the present disclosure, in consideration of aspects of stress and resistance uniformity, on the basis of that the second plates of the storage capacitors of all the blocks 501 within the bank 519 are all connected, also as shown in FIG. 6A, the second plates of the storage capacitors may be not led out with the bank 519 as a unit, a plurality of first conductive connection structures are uniformly disposed within the bank, and the number of the first conductive connection structures is less than the number of the blocks within the bank. In an example of the present disclosure, the number and distribution of the first conductive connection structures within the bank may be flexibly selected by comprehensive considering requirements in aspects of stress, resistance uniformity, and a memory area.

Here, that the second plates 505 of the storage capacitors 503 of at least two banks 519 in the plurality of banks 519 are connected may be understood as that the second plates of the storage capacitors of all the blocks within the bank are all connected; the second plates of the storage capacitors of one bank are connected to the second plates of the storage capacitors of another bank; the number of banks in which the second plates of the storage capacitors are connected to each other is greater than or equal to two. In this way, the second plates of the storage capacitors may be led out with the plurality of banks as a unit, such that the number of the first conductive connection structures can be further reduced. Here, the number and distribution of the first conductive connection structures within the bank may also be flexibly selected based on use-case considerations such as stress, resistance uniformity, and a memory area.

In an example of the present disclosure, the second plates of all the storage capacitors within the bank group may be connected, none of the second plates of the storage capacitors may be connected between the bank groups, or the second plates of the storage capacitors of at least two bank groups are connected.

In some examples, the second plates 505 of the storage capacitors 503 of the plurality of banks 519 within the chip are all connected.

That the second plates 505 of the storage capacitors 503 of the plurality of banks 519 within the chip are all connected may be understood as that the storage capacitors of all the blocks within one chip are all connected. That is, the second plates of all the storage capacitors within the block are connected, the second plates of the storage capacitors of all the blocks within the bank are connected, and the second plates 505 of the storage capacitors of all the blocks within the chip are connected. It may be understood that the second plates 505 of the storage capacitors 503 of all the banks 519 within the chip are all connected, such that the second plates of the storage capacitors of the chip may be led out with the chip as a unit; thus, the number of the first conductive connection structures can be further reduced. In addition, a mask required for disconnecting the second plate is unnecessary, and a process for disconnecting the second plate can be omitted, such that process costs can be reduced. Here, the number and distribution of the first conductive connection structures within the bank may also be flexibly selected by comprehensive considering requirements in aspects of stress, resistance uniformity, and a memory area.

In some examples, as shown in FIG. 6A and FIG. 6B, the plurality of blocks 501 are arranged in an array along a second direction perpendicular to a first direction and a third direction perpendicular to the first direction; the second direction intersects the third direction; the first direction is a thickness direction of the block 501; the block 501 includes a memory region 508 and a contact region 509, where the contact region 509 is located on two opposite sides of the memory region 508 along the second direction and two opposite sides of the memory region 508 along the third direction; and the first conductive connection structure 507 is located in the contact region 509 of the block 501.

In an example of the present disclosure, the first direction may be a Z-axis direction in the drawings, the second direction may be an X-axis direction in the drawings, and the third direction may be a Y-axis direction in the drawings. The second direction intersects the third direction, an example in which the second direction is perpendicular to the third direction is used for description in the examples of the present disclosure.

In an example of the present disclosure, the contact region 509 surrounds the memory region 508, the first conductive connection structure 507 is located in the contact region 509.

In some examples, as shown in FIG. 6A and FIG. 6B, the first conductive connection structure 507 is located in the contact region 509 at a corner of the block 501.

As shown in FIG. 6A, as seen from the entire bank, the contact region includes a portion extending along the second direction and a portion extending along the third direction, an overlapping portion between the portion extending along the second direction and the portion extending along the third direction is the contact region at the corner of the block; that is, a position shown by a dash line in FIG. 6A.

It may be understood that, in an example of the present disclosure, there may be other routings in the contact region 509 between the memory region 508 of the block 501 and the memory region 508 of the adjacent block 501. Therefore, the first conductive connection structure 507 may be disposed in the contact region 509 at the corner of the block 501. In this way, process difficulty can be reduced, and interference between routings can be reduced.

In some examples, as shown in FIG. 4, the block 501 further includes a second semiconductor structure 510 disposed as being stacked with the first semiconductor structure 502 along the first direction, the second semiconductor structure 510 includes a peripheral circuit 210. The first conductive connection structure 507 is located between the second semiconductor structure 510 and the second plate 505. The memory cell array 220 further includes a plurality of transistors 512, where the transistor 512 is located between the storage capacitor 503 and the second semiconductor structure 510, the transistor 512 includes a source 514, a channel region 513, and a drain 515 arranged along the first direction, and one of the source 514 and the drain 515 of the transistor 512 is connected to the first plate 504 of the storage capacitor 503. The memory cell array 220 further includes the first semiconductor structure 502 further includes: a plurality of bit lines 516, where the bit line 516 is located between the transistor 512 and the second semiconductor structure 510, and the other one of the source 514 and the drain 515 of the transistor 512 is connected to the bit line 516.

In some examples, the transistor 512 in the examples of the present disclosure may be a vertical transistor shown in FIG. 4 and FIG. 5. However, the present disclosure is not limited thereto. The transistor 512 in the present disclosure may also be a planar transistor. A material of the bit line 516 may include a conductive material, including a metal material and a metal silicide, the metal material includes, but is not limited to, tungsten, titanium, tantalum, aluminum, etc., and the metal silicide includes, but is not limited to, tungsten silicide, nickel silicide, cobalt silicide, and titanium silicide.

In some examples, as shown in FIG. 5, the first semiconductor structure further includes a word line 545, which may be used as a gate of the transistor 512. The word line 545 may be located on one side of the channel region, or may be located on two sides or three sides of the channel region or around the channel region.

In some examples, as shown in FIG. 4, the second plate 505 extends from the memory region 508 into the contact region 509, and the second plate 505 located in the memory region 508 includes a first portion 518 extending along the first direction and a second portion 517 extending along a direction perpendicular to the first direction; the second plate 505 located in the contact region 509 extends along the direction perpendicular to the first direction; a distance between the second plate 505 in the contact region 509; and the transistor 512 along the first direction is less than a distance between the second portion 517 of the second plate 505 in the memory region 508 and the transistor 512 along the first direction.

It may be understood that, in an example of the present disclosure, since the distance between the second plate 505 in the contact region 509 and the transistor 512 along the first direction is less than the distance between the second portion 517 of the second plate 505 in the memory region 508 and the transistor 512 along the first direction, and the first conductive connection structure 507 is connected to the second plate 505 in the contact region 509, a size of the first conductive connection structure 507 along the first direction is clearly reduced compared with the example shown in FIG. 3; in this way, the manufacturing difficulty of the first conductive connection structure 507 can be reduced. In some examples, a size of the first conductive connection structure 507 along the first direction in the example shown in FIG. 4 is about 1 micrometer smaller than the size of the first conductive connection structure 507 along the first direction in the example shown in FIG. 3. In addition, in the example shown in FIG. 3, since the size of the first conductive connection structure 507 along the first direction is large, a size of the first conductive connection structure 507 along the direction perpendicular to the first direction needs to be designed to be large to reduce process difficulty. In the example shown in FIG. 4, since the size of the first conductive connection structure 507 along the first direction is significantly reduced, process requirements can be met when the size of the first conductive connection structure 507 along the direction perpendicular to the first direction is designed to be small in the example shown in FIG. 4, such that the area of the memory can be further reduced. Moreover, in the example shown in FIG. 4, since the first conductive connection structure 507 may be directly connected to the second plate 505 without a first metal layer 511 and a contact structure 538 additionally disposed at the bottom as in the example shown in FIG. 3, such that the structure of the memory can be simplified, and process operations are reduced, thereby reducing process costs.

In some examples, the peripheral circuit 210 is located in the memory region 508, the memory cell array 220 is located in the memory region 508, and projections of the memory region 508 in which the memory cell array 220 is located and the memory region 508 in which the peripheral circuit 210 is located along a first plane overlap, the first plane is perpendicular to the first direction.

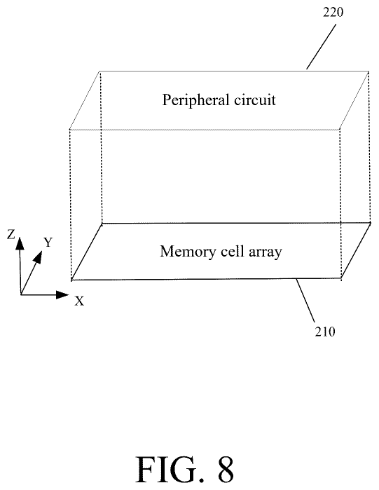

As shown in FIG. 8, the first plane here may be understood as a plane in which an X-axis and a Y-axis are located. That the projections of the memory region 508 in which the memory cell array 220 is located and the memory region 508 in which the peripheral circuit 210 is located along the first plane overlap may be understood as that an area occupied by the peripheral circuit 210 is equal to that occupied by the memory cell array 220, and in the first plane, the projections of both may completely overlap. In this way, the area of the memory can be reduced, to avoid that one of the memory cell array and the peripheral circuit occupies a larger area so as to waste the area of the memory region in which the other one of the memory cell array and the peripheral circuit is located. In addition, on the basis of that the second plates 505 of the storage capacitors 503 of at least two blocks 501 of the plurality of blocks 501 are connected, since it is unnecessary that the separate first conductive connection structure 507 is disposed for every block 501, it is unnecessary that a region for forming the first conductive connection structure 507 is additionally reserved for the contact region 509 corresponding to every block 501. Therefore, a width of the contact region 509 for which the first conductive connection structure 507 does not need to be disposed may be designed to be small such that the area of the memory can be further reduced.

In some examples, the peripheral circuit 210 includes a sensing amplifier circuit, a word-line driver circuit, a row decoder, a column decoder, a command buffer, a command decoder, an address buffer, a data input/output buffer, a mode register, etc.

In some examples, as shown in FIG. 4, the second semiconductor structure 510 further includes a first interconnect layer 520 located between the first semiconductor structure 502 and the peripheral circuit 210, where the first interconnect layer 520 includes a first interconnect structure 521; the first semiconductor structure 502 further includes a second interconnect layer 522 located between the memory cell array 220 and the second semiconductor structure 510, where the second interconnect layer 522 includes a second interconnect structure 523; and the peripheral circuit 210 is coupled to the memory cell array 220 through the first interconnect structure 521 and the second interconnect structure 523.

In some examples, the block 501 further includes a bonding interface, where the bonding interface is located between the first interconnect layer 520 and the second interconnect layer 522, and the first interconnect structure 521 is coupled to the second interconnect structure 523 through the bonding interface.

The memory in an example of the present disclosure may be formed by bonding two wafers. For example, a partial structure of the first semiconductor structure 502 may be formed on one wafer, a partial structure of the second semiconductor structure 510 may be formed on the other wafer, and then the two wafers are bonded. The memory shown in FIG. 4 is formed by bonding two wafers, the first semiconductor structure 502 and the second semiconductor structure 510 are stacked along the first direction. In some other examples, the first semiconductor structure 502 and the second semiconductor structure 510 in the memory may also be formed on a same wafer, but the first semiconductor structure 502 and the second semiconductor structure 510 are stacked along the first direction. Compared with the architecture in which the first semiconductor structure 502 and the second semiconductor structure 510 are arranged in juxtaposition along the direction perpendicular to the first direction, the architecture in which the first semiconductor structure 502 and the second semiconductor structure 510 are both disposed as being stacked along the first direction can save more of the area of the memory.

In some examples, as shown in FIG. 4, the second semiconductor structure 510 further includes a substrate 524 and a bus layer 525, the peripheral circuit 210 is located in the substrate 524, and the substrate 524 is located between the bus layer 525 and the first semiconductor structure 502.

In some examples, the substrate 524 may include an elemental semiconductor material substrate (e.g., a silicon (Si) substrate, a germanium (Ge) substrate, and the like), a composite semiconductor material substrate (e.g., a silicon germanium (SiGe) substrate), a silicon-on-insulator (SOI) substrate, a germanium-on-insulator (GeOI) substrate, and the like. In an example, the substrate 524 is a silicon substrate.

Here, a bus is formed in the bus layer 525, and the bus includes at least one of the following: a data bus, a control bus, a power bus, a ground bus, a signal bus, etc.

It may be understood that, in the above example, the substrate 524 may include a front surface and a rear surface, the front surface and the rear surface are two opposite surfaces of the substrate 524 along the first direction, the peripheral circuit 210 is formed on the front surface of the substrate 524, and the bus layer 525 is formed on the rear surface of the substrate 524. The peripheral circuit 210 is located between the bus layer 525 and the first semiconductor structure 502, and the first semiconductor structure 502 includes the bit line 516; that is, the peripheral circuit 210 is located between the bus layer 525 and the bit line 516. Compared with the solution in which the bus layer 525 is disposed between the peripheral circuit 210 and the bit line 516, the solution in which the peripheral circuit 210 is located between the bus layer 525 and the bit line 516 has the following benefits. For instance, in the solution in which the peripheral circuit 210 is located between the bus layer 525 and the bit line 516, the bus layer 525 is far away from both the peripheral circuit 210 and the bit line 516, such that crosstalk among the bus, the peripheral circuit 210, and the bit line 516 can be reduced, and the impact on a sense margin can be reduced, thereby improving the performance of the memory; in another aspect, a lane of a metal layer of the bus is not restricted by the position of a bonding conductive connection structure in the memory formed by bonding the first semiconductor structure 502 and the second semiconductor structure 510, such that there are more routing channels of the metal layer of the bus, thereby improving the routing flexibility.

In some examples, as shown in FIG. 4, the second semiconductor structure 510 further includes a second conductive connection structure 526, where the second conductive connection structure 526 extends through the substrate 524, one end of the second conductive connection structure 526 is connected to the bus in the bus layer 525, and the other end of the second conductive connection structure 526 is connected to the first interconnect structure 521.

The second conductive connection structure 526 here may be a through silicon via structure. The second conductive connection structure 526 may connect the peripheral circuit 210 to the bus in the bus layer 525.

In some examples, as shown in FIG. 4, the second semiconductor structure 510 further includes a pad-out interconnect layer 527, and the peripheral circuit 210 is located between the pad-out interconnect layer 527 and the first semiconductor structure 502.

In some examples, as shown in FIG. 4, the pad-out interconnect layer 527 includes a pad structure 540. When the memory needs to be connected to an external device, electrical lead-out can be implemented through the pad structure 540.

In some examples, a material of the second conductive connection structure 526 includes a conductive material, and may include, e.g., a metal material (e.g., tungsten, titanium, tantalum, aluminum, etc.). A material of the pad structure 540 includes a conductive material, and may include, e.g., a metal material (e.g., tungsten, titanium, tantalum, aluminum, etc.).

It may be understood that compared with the solution in which the pad structure 540 is disposed on the rear surface of the first semiconductor structure 502, the solution in which the pad structure 540 is disposed on the rear surface of the substrate 524 of the second semiconductor structure 510 can reduce a routing length from the bit line 516 to the peripheral circuit 210.

Based on a similar conception to the memory in the above examples, an example of the present disclosure further provide a memory system 30, where the memory system 30 includes a controller 10 and the memory 20 described in any one of the above examples, the controller 10 is configured to control the memory 20.

The above-mentioned memory system 30 has been illustrated in detail in the foregoing examples with respect to FIG. 1, which will not be repeated here for brevity.

Based on the similar concept to the memory in the above examples, an example of the present disclosure further provide a forming method of a memory.

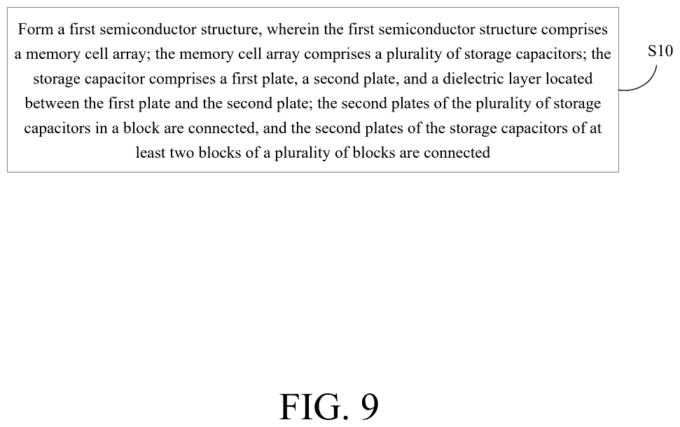

FIG. 9 is a flow chart illustrating a forming method of a memory according to an example of the present disclosure. Referring to FIG. 9, the forming method includes the following.

Operation S10: forming a plurality of blocks, where forming each of the blocks at least includes the following operations: forming a first semiconductor structure, where the first semiconductor structure includes a memory cell array, which includes a plurality of storage capacitors, the storage capacitor includes a first plate, a second plate, and a dielectric layer located between the first plate and the second plate, the second plates of the plurality of storage capacitors in the block are connected, and the second plates of the storage capacitors of at least two blocks of the plurality of blocks are connected.

In some examples, forming the first semiconductor structure further includes: forming a first conductive connection structure in each of the first semiconductor structures of at least part of the blocks, where the first conductive connection structure is connected to the second plate.

In some examples, a via may be formed in a corresponding dielectric layer through a dry etching process, and then a conductive material is deposited in the via to form the first conductive connection structure.

In an example of the present disclosure, the deposition process includes, but is not limited to, chemical vapor deposition (CVD), low pressure chemical vapor deposition (LPCVD), plasma enhanced chemical vapor deposition (PECVD), physical vapor deposition (PVD), and atomic layer deposition (ALD).

In some examples, the plurality of blocks are arranged in an array along a second direction perpendicular to a first direction and a third direction perpendicular to the first direction, where the second direction intersects the third direction, and the first direction is a thickness direction of the block; the block includes a memory region and a contact region, where the contact region is located on two opposite sides of the memory region along the second direction and two opposite sides of the memory region along the third direction; and the forming the first conductive connection structure includes: forming the first conductive connection structure in the contact region of the block.

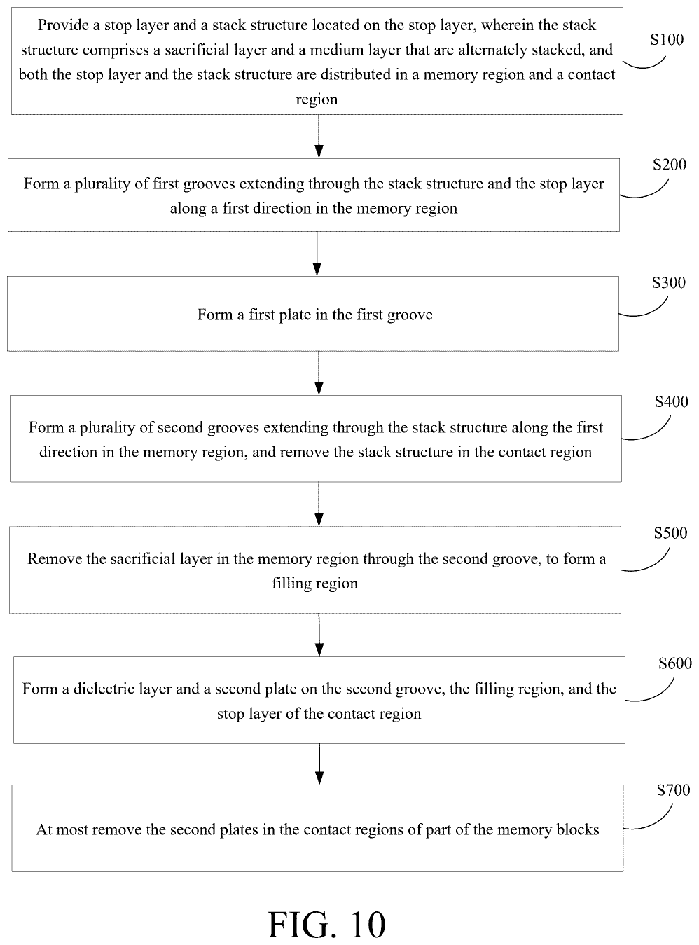

In some examples, as shown in FIG. 10, forming the plurality of storage capacitors includes the following operations.

Operation S100: providing a stop layer and a stack structure located on the stop layer, where the stack structure includes a sacrificial layer and a dielectric layer that are alternately stacked, and both the stop layer and the stack structure are distributed in the memory region and the contact region.

Operation S200: forming a plurality of first grooves extending through the stack structure and the stop layer along the first direction in the memory region.

Operation S300: forming the first plate in the first groove.

Operation S400: forming a plurality of second grooves extending through the stack structure along the first direction in the memory region, and removing the stack structure in the contact region.

Operation S500: removing the sacrificial layer in the memory region through the second groove to form a filling region.

Operation S600: forming the dielectric layer and the second plate on the second groove, the filling region, and the stop layer of the contact region; operation S700: at most removing the second plates in the contact regions of part of the blocks.

It should be understood that the operations as illustrated in FIG. 10 are not exclusive, and other operations may be also performed before, after, or between any of the illustrated operations. A sequence of the operations illustrated in FIG. 10 can be adjusted according to actual needs.

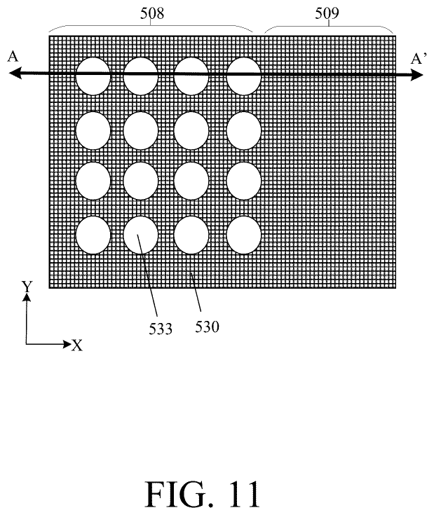

FIG. 11 to FIG. 21 are schematic diagrams of a forming process of a memory shown in an example of the present disclosure. A forming method of a memory provided by the example of the present disclosure is exemplarily described below in conjunction with FIG. 11 to FIG. 21.

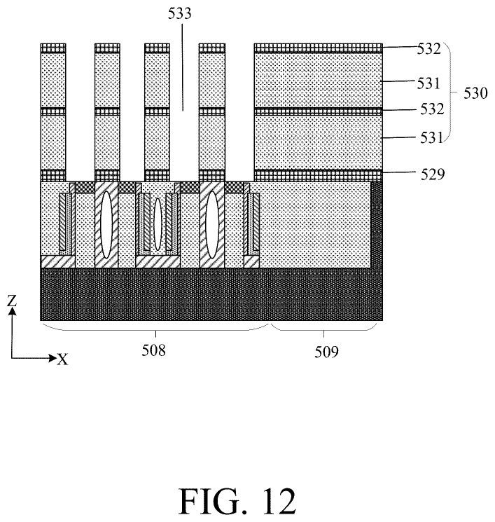

As shown in FIG. 11 and FIG. 12, a stop layer 529 and a stack structure 530 located on the stop layer 529 are provided, where the stack structure 530 includes a sacrificial layer 531 and a dielectric layer 532 that are alternately stacked, and both the stop layer 529 and the stack structure 530 are distributed in the memory region 508 and the contact region 509; and a plurality of first grooves 533 extending through the stack structure 530 and the stop layer 529 along the first direction are formed in the memory region 508.

FIG. 12 is a cross-sectional view of FIG. 11 along a direction AA′. FIG. 11 is a schematic structural top view.

In some examples, the above-mentioned stack structure 530 may be formed through a deposition process, and the above-mentioned first groove 533 is formed through a dry etching process. The first groove 533 here may have a hole shape or other shapes, and the first groove 533 extends through the stack structure 530 along the first direction. In some examples, a material of the stop layer 529 includes, but is not limited to, silicon boron nitride, a material of the dielectric layer 532 includes, but is not limited to, silicon carbon nitride, and a material of the sacrificial layer 531 includes, but is not limited to, silicon oxide.

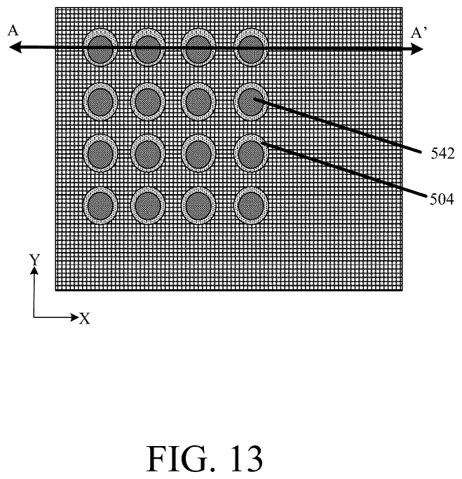

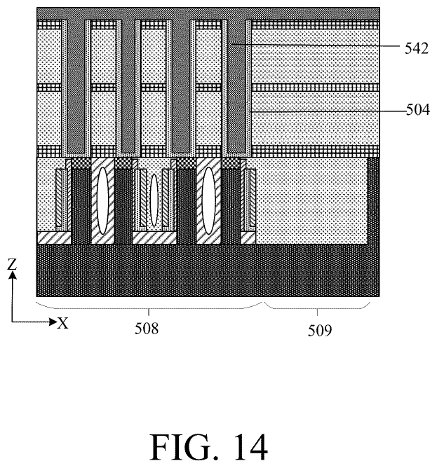

As shown in FIG. 13 and FIG. 14, the first plate 504 and a support structure 542 are formed in the first groove 533, the first plate 504 is located on a side wall and a bottom wall of the first groove 533, and the support structure 542 is located in the first groove 533, covers the first plate 504, and is located on the stack structure 530. In some examples, a material of the support structure 542 includes, but is not limited to, polysilicon.

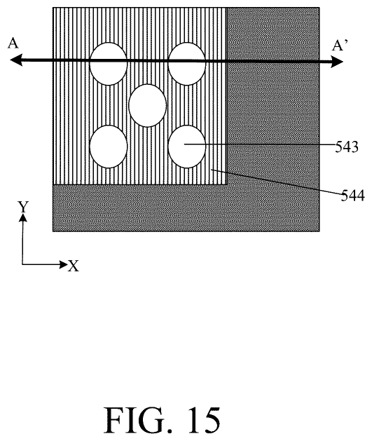

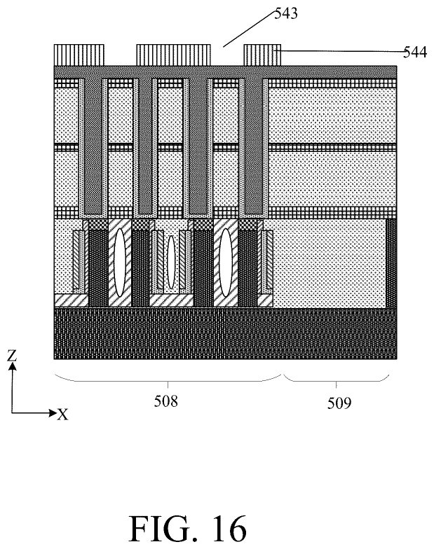

As shown in FIG. 15 and FIG. 16, a mask layer 544 is formed on the support structure 542, a third groove 543 is formed in the mask layer 544, and the third groove 543 exposes the support structure 542 of the contact region 509 and a part of the support structure 542 of the memory region 508.

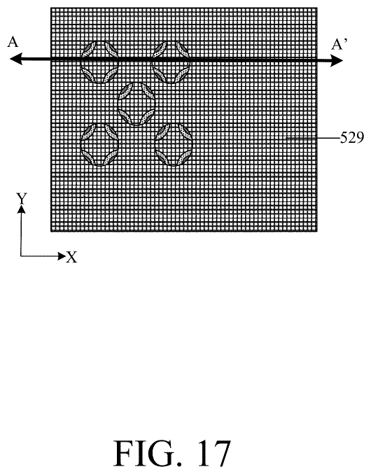

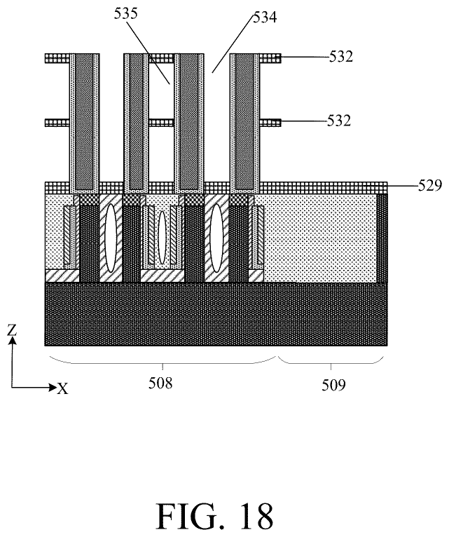

As shown in FIG. 17 and FIG. 18, a plurality of second grooves 534 extending through the stack structure 530 along the first direction are formed in the memory region 508 through a dry etching process, the second grooves 534 expose the surface of the stop layer 529 and the sacrificial layer 531 in the stack structure 530 in the memory region 508, while the stack structure 530 in the contact region 509 is removed through a dry etching process to expose the stop layer in the contact region; and the sacrificial layer 531 in the memory region 508 is removed from the second groove 534 through a wet etching process, to form a filling region 535. In some examples, the above method further includes removing the mask layer and removing a part of the support structure, such that a top surface of the support structure is flush with a top surface of the first plate.

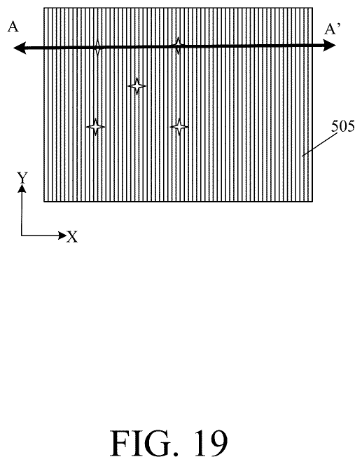

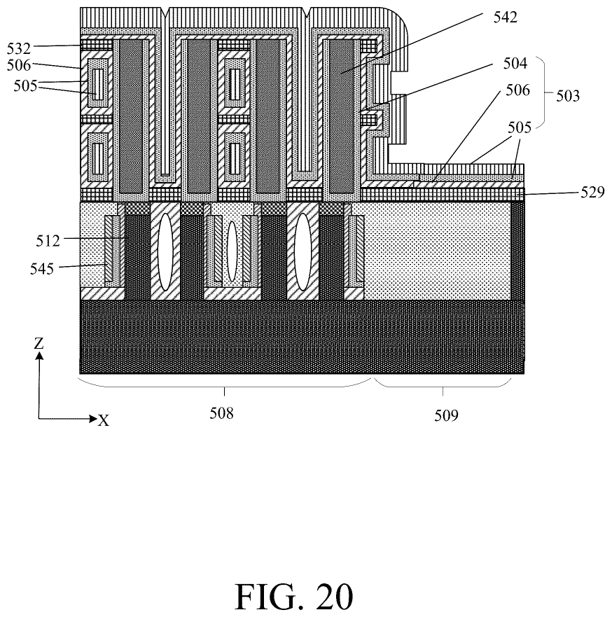

As shown in FIG. 19 and FIG. 20, the dielectric layer 506 and the second plate 505 are formed on the second groove 534, the filling region 535, and the stop layer 529 of the contact region 509. The dielectric layer 506 is located between the first plate 504 and the second plate 505, the dielectric layer 506 and the second plate 505 are not only located on the filling region 535, the second groove 534, and the stop layer 529 of the contact region 509, but also located on the dielectric layer 532 in an upper layer of the stack structure 530 and the support structure 542.

In an example of the present disclosure, at most the second plates 505 in the contact regions 509 of part of the blocks 501 are removed. That is, the second plates in the contact regions of at least part of the blocks are not removed. In this way, the second plates of the storage capacitors of one block may be connected to the second plates of the storage capacitors of another block. In some examples, the dielectric layer in the contact region in which the second plate is not removed is also not removed. In a case that none of the second plates of the contact regions of all the blocks within the chip is removed, a mask required for disconnecting the second plate can be saved, and a disconnecting procedure for the second plate is omitted, such that a process time can be reduced, and process costs are reduced.

In some examples, forming the block further includes: forming a second semiconductor structure disposed as being stacked with a first semiconductor structure along the first direction, where the second semiconductor structure includes a peripheral circuit, and the first conductive connection structure is located between the second semiconductor structure and the second plate; and forming the first semiconductor structure includes: forming a plurality of transistors, where the transistor is located between the storage capacitor and the second semiconductor structure, the transistor includes a source, a channel region, and a drain arranged along the first direction, and one of the source and the drain of the transistor is connected to the first plate of the storage capacitor; and forming a plurality of bit lines, where the bit line is located between the transistor and the second semiconductor structure, and the other one of the source and the drain of the transistor is connected to the bit line.

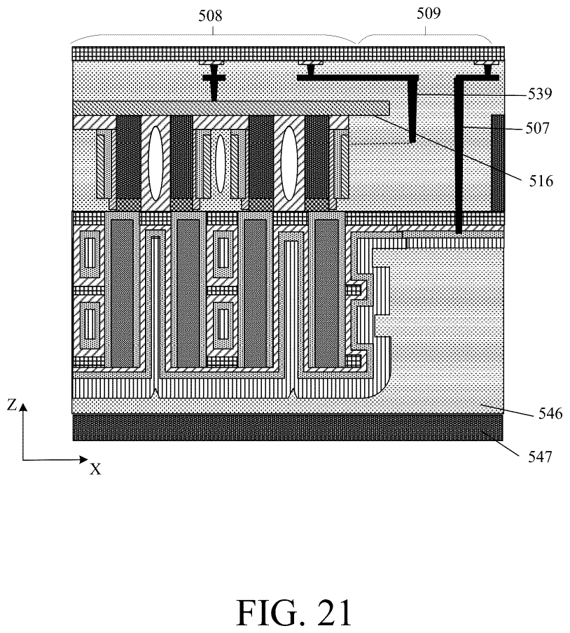

In some examples, as shown in FIG. 21, the method further includes: after forming a memory structure, forming a first dielectric layer 546 covering the memory structure, and forming a carrier wafer 547 on the first dielectric layer 546. The above-mentioned formed structure is turned over, such that the carrier wafer 547 is located at the bottom, and a substrate is removed to form a bit line 516, a first conductive connection structure 507, and a third conductive connection structure 539. As for the formation of the first conductive connection structure 507 and third conductive connection structure 539, a via may be formed in a corresponding dielectric layer, and a conductive material is filled within the via, such that the first conductive connection structure 507 and the third conductive connection structure 539 are formed.

In some examples, forming the first semiconductor structure 502 further includes: forming a third conductive connection structure 539 while forming the first conductive connection structure 507, where the third conductive connection structure 539 is connected to the bit line 516.

It may be understood that, in the examples of the present disclosure, since the first conductive connection structure 507 may be connected to the second plate 505 of the contact region 509, a size of the first conductive connection structure 507 along the first direction is reduced, such that the first conductive connection structure 507 may be formed at the same time as the third conductive connection structure 539 with an approximate size. In this way, process operations can be reduced, thereby reducing process costs.

In some examples, the second plate 505 extends from the memory region 508 into the contact region 509, the second plate 505 located in the memory region 508 includes a first portion 518 extending along the first direction and a second portion 517 extending along a direction perpendicular to the first direction, and the second plate 505 located in the contact region 509 extends along the direction perpendicular to the first direction; and a distance between the second plate 505 in the contact region 509 and the transistor 512 along the first direction is less than a distance between the second portion 517 of the second plate 505 in the memory region 508 and the transistor 512 along the first direction.

In some examples, forming the second semiconductor structure includes: providing a substrate, where the substrate includes a first side and a second side that are opposite along a thickness direction of the substrate; forming the peripheral circuit in the substrate from the first side; and forming a first interconnect layer on the peripheral circuit from the first side, where the first interconnect layer includes a first interconnect structure.

In some examples, forming the second semiconductor structure further includes: forming a bus layer on the substrate from the second side; and forming a pad-out interconnect layer on the bus layer from the second side. The first side here may be the front surface in the foregoing example, and the second side may be the rear surface in the foregoing example.

In some examples, forming the first semiconductor structure 502 further includes: forming a second interconnect layer, where the second interconnect layer includes a second interconnect structure, and the bit line is located between the memory cell array and the second interconnect layer.

In some examples, the method further includes: bonding the first interconnect layer of the second semiconductor structure and the second interconnect layer of the first semiconductor structure to form a bonding interface, such that the first interconnect structure is coupled to the second interconnect structure.

In some examples, the first interconnect layer of the second semiconductor structure and the second interconnect layer of the first semiconductor structure may be bonded through a hybrid bonding process.

It is to be noted that, the present disclosure is not limited to the forming method for bonding the first semiconductor structure 502 and the second semiconductor structure in the above examples, furthermore the first semiconductor structure and the second semiconductor structure may be formed on a same wafer.

The features disclosed in several device examples provided by the present disclosure may be combined arbitrarily to obtain a new device example in the case of no conflicts.

The methods disclosed in several method examples provided by the present disclosure can be combined arbitrarily to obtain a new method example in case of no conflicts.

The above is only the implementations of the present disclosure, the scope of protection of the present disclosure is not limited thereto. Any variations or replacements that easily occurred to those skilled in the art within the technical scope disclosed by the present disclosure shall fall within the scope of protection of the present disclosure.

What is claimed is:

1. A memory, comprising:
a plurality of blocks each comprising a first semiconductor structure;
wherein the first semiconductor structure comprises a memory cell array; the memory cell array comprises a plurality of storage capacitors; the storage capacitor comprises a first plate, a second plate, and a dielectric layer located between the first plate and the second plate; the second plates of the plurality of storage capacitors in the block are connected, and the second plates of the storage capacitors of at least two blocks of the plurality of blocks are connected.

2. The memory of claim 1, wherein each of the first semiconductor structures of at least part of the plurality of blocks further comprises a first conductive connection structure, and wherein the first conductive connection structure is connected to the second plate.

3. The memory of claim 2, wherein the plurality of blocks are arranged in an array along a second direction perpendicular to a first direction and a third direction perpendicular to the first direction, wherein the second direction intersects the third direction, and the first direction is a thickness direction of the block, wherein each block further comprises a memory region and a contact region, wherein the contact region is located on two opposite sides of the memory region along the second direction and two opposite sides of the memory region along the third direction, wherein the first conductive connection structure is located in the contact region of the block, and wherein the first conductive connection structure is located in the contact region at a corner of the block.

4. The memory of claim 3, wherein the block further comprises a second semiconductor structure disposed as being stacked with the first semiconductor structure along the first direction, wherein the second semiconductor structure comprises a peripheral circuit, the first conductive connection structure is located between the second semiconductor structure and the second plate, and the memory cell array further comprises:
a plurality of transistors, wherein each transistor is located between the storage capacitor and the second semiconductor structure, each transistor comprises a source, a channel region, and a drain arranged along the first direction, and one of the source and the drain of the transistor is connected to the first plate of the storage capacitor; and
the first semiconductor structure further comprises: a plurality of bit lines, wherein the bit line is located between the transistor and the second semiconductor structure, and the other one of the source and the drain of the transistor is connected to the bit line.

5. The memory of claim 4, wherein the second plate extends from the memory region into the contact region, the second plate located in the memory region comprises a first portion extending along the first direction and a second portion extending along a direction perpendicular to the first direction, and the second plate located in the contact region extends along the direction perpendicular to the first direction, wherein a distance between the second plate in the contact region and the transistor along the first direction is less than a distance between the second portion of the second plate in the memory region and the transistor along the first direction.

6. The memory of claim 4, wherein the peripheral circuit is located in the memory region, the memory cell array is located in the memory region, and projections of the memory region in which the memory cell array is located and the memory region in which the peripheral circuit is located along a first plane overlap, wherein the first plane is perpendicular to the first direction.

7. The memory of claim 1, wherein the memory comprises at least one chip, the chip comprises a plurality of banks, wherein the bank comprises the plurality of blocks, the second plates of the storage capacitors of the plurality of blocks in the bank are all connected, and the second plates of the storage capacitors of at least two banks of the plurality of banks are connected.

8. The memory of claim 7, wherein the second plates of the storage capacitors of the plurality of banks within the chip are all connected.

9. The memory of claim 4, wherein the second semiconductor structure further comprises a first interconnect layer located between the first semiconductor structure and the peripheral circuit, wherein the first interconnect layer comprises a first interconnect structure, wherein the first semiconductor structure further comprises a second interconnect layer located between the memory cell array and the second semiconductor structure, wherein the second interconnect layer comprises a second interconnect structure, wherein the peripheral circuit is coupled to the memory cell array through the first interconnect structure and the second interconnect structure, and wherein the second semiconductor structure further comprises a substrate and a bus layer, wherein the peripheral circuit is located in the substrate, and the substrate is located between the bus layer and the first semiconductor structure.

10. The memory of claim 9, wherein the second semiconductor structure further comprises a second conductive connection structure, wherein the second conductive connection structure extends through the substrate, one end of the second conductive connection structure is connected to a bus in the bus layer, and the other end of the second conductive connection structure is connected to the first interconnect structure.

11. The memory of claim 5, wherein the second semiconductor structure further comprises a pad-out interconnect layer, wherein the peripheral circuit is located between the pad-out interconnect layer and the first semiconductor structure.

12. A memory system, comprising:
a memory comprising:
a plurality of blocks each comprising a first semiconductor structure;
the first semiconductor structure comprises a memory cell array; the memory cell array comprises a plurality of storage capacitors; the storage capacitor comprises a first plate, a second plate, and a dielectric layer located between the first plate and the second plate; the second plates of the plurality of storage capacitors in the block are connected, and the second plates of the storage capacitors of at least two blocks of the plurality of blocks are connected; and
a controller configured to control the memory.

13. A method of forming a memory, comprising:
forming a plurality of blocks, wherein the forming each block comprises:
forming a first semiconductor structure, wherein the first semiconductor structure comprises a memory cell array, wherein the memory cell array comprises a plurality of storage capacitors, wherein the storage capacitor comprises a first plate, a second plate, and a dielectric layer located between the first plate and the second plate, and wherein the second plates of the plurality of storage capacitors in the block are connected, and the second plates of the storage capacitors of at least two blocks of the plurality of blocks are connected.

14. The method of claim 13, wherein the forming the first semiconductor structure further comprises:
forming a first conductive connection structure in each of the first semiconductor structures of at least part of the blocks, wherein the first conductive connection structure is connected to the second plate.

15. The method of claim 14, wherein the plurality of blocks are arranged in an array along a second direction perpendicular to a first direction and a third direction perpendicular to the first direction, wherein the second direction intersects the third direction, and the first direction is a thickness direction of the block, wherein each block comprises a memory region and a contact region, wherein the contact region is located on two opposite sides of the memory region along the second direction and two opposite sides of the memory region along the third direction, and wherein the forming the first conductive connection structure comprises:
forming the first conductive connection structure in the contact region of the block.

16. The method of claim 15, wherein the forming the plurality of storage capacitors comprises:
providing a stop layer and a stack structure located on the stop layer, wherein the stack structure comprises a sacrificial layer and a dielectric layer that are alternately stacked, and both the stop layer and the stack structure are distributed in the memory region and the contact region;
forming a plurality of first grooves extending through the stack structure and the stop layer along the first direction in the memory region;
forming the first plate in the first groove;
forming a plurality of second grooves extending through the stack structure along the first direction in the memory region, and removing the stack structure in the contact region;
removing the sacrificial layer in the memory region through the second groove, to form a filling region;
forming the dielectric layer and the second plate on the second groove, the filling region, and the stop layer of the contact region; and
removing the second plates in the contact regions of part of the blocks.

17. The method of claim 15, wherein:
the forming each block further comprises:
forming a second semiconductor structure disposed as being stacked with the first semiconductor structure along the first direction, wherein the second semiconductor structure comprises a peripheral circuit, and the first conductive connection structure is located between the second semiconductor structure and the second plate; and
forming the first semiconductor structure comprises:
forming a plurality of transistors, wherein the transistor is located between the storage capacitor and the second semiconductor structure, the transistor comprises a source, a channel region, and a drain arranged along the first direction, and one of the source and the drain of the transistor is connected to the first plate of the storage capacitor; and
forming a plurality of bit lines, wherein the bit line is located between the transistor and the second semiconductor structure, and the other one of the source and the drain of the transistor is connected to the bit line.

18. The method of claim 17, wherein the second plate extends from the memory region into the contact region, the second plate located in the memory region comprises a first portion extending along the first direction and a second portion extending along a direction perpendicular to the first direction, and the second plate located in the contact region extends along the direction perpendicular to the first direction; and a distance between the second plate in the contact region and the transistor along the first direction is less than a distance between the second portion of the second plate in the memory region and the transistor along the first direction.

19. The method of claim 17, wherein the forming the first semiconductor structure further comprises:
forming a third conductive connection structure while forming the first conductive connection structure, wherein the third conductive connection structure is connected to the bit line.

20. The method of claim 17, wherein the forming the second semiconductor structure comprises:
providing a substrate, wherein the substrate comprises a first side and a second side that are opposite along a thickness direction of the substrate;
forming the peripheral circuit in the substrate from the first side;
forming a first interconnect layer on the peripheral circuit from the first side, wherein the first interconnect layer comprises a first interconnect structure;
forming a bus layer on the substrate from the second side; and
forming a pad-out interconnect layer on the bus layer from the second side.
